(19) United States
(12) Patent Application Publication
(10) Pub. No.: US 2008/0037215 A1
(43) Pub. Date: Feb. 14, 2008

(54) External box structure with inner and outer tracks

(76) Inventor: Jen-Hung Wang, Chung Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/878,185

(22) Filed: Jul. 23, 2007

(30) Foreign Application Priority Data
Aug. 8, 2006 (TW) 95213935

(51) Int. Cl. H05K 7/20; H05K 5/00

(52) U.S. Cl. 361/688; 361/724

(57) ABSTRACT

An external box structure with inner and outer tracks includes a casing body, a cover body, and a fixed board. The cover body is assembled on the casing body and has two first retaining portions respectively formed on two sides thereof. The fixed board has a second retaining portion. The second retaining portion slidably mates with any one of the two first retaining portions for fixing the casing body on the fixed board. Therefore, the external box structure is positioned on the fixed board in a lateral direction for reducing its required space.

### BACKGROUND OF THE INVENTION

1. Field of the Invention

The present invention relates to an external box structure, and particularly relates to an external box structure with inner and outer tracks.

2. Description of the Related Art

An external box of the prior art is used to receive a hard disk and has a built-in USB port for supporting low-speed data transmission such as that transmitted by a mouse, a keyboard, or a joystick, etc., and for supporting high-speed digital compression images, too. Moreover, the external box has a hard disk switch and supports a number of types of operating systems.

The external box of the prior art has a top casing body and a bottom casing body. The bottom casing body has a receiving space for receiving the hard disk. The bottom casing has a plurality of function ports and switches. The top casing body mates with the bottom casing body.

However, the prior external box can only be positioned in a horizontal direction. Hence, the prior external box occupies a large space.

### SUMMARY OF THE INVENTION

The present invention provides an external box structure with inner and outer tracks. A cover body has two first retaining portions respectively formed on two sides thereof. A fixed board has a second retaining portion. Because the second retaining portion slidably mates with any one of the two first retaining portions, the casing body is fixed on the fixed board. Therefore, the external box structure is positioned on the fixed board in a lateral direction for reducing space.

A first aspect of the present invention is an external box structure with inner and outer tracks, comprising: a casing body, a cover body, and a fixed board. The cover body is assembled on the casing body and has two first retaining portions respectively formed on two sides thereof. The fixed board has a second retaining portion. The second retaining portion slidably mates with any one of the two first retaining portions for fixing the casing body on the fixed board.

A second aspect of the present invention is an external box structure with inner and outer tracks, comprising: a casing body and a cover body. The cover body is assembled on the casing body and has two first retaining portions respectively formed on two sides thereof.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a perspective, exploded view of an external box structure with inner and outer tracks of the present invention;

FIG. 2 is a perspective, assembled view of an external box structure with inner and outer tracks of the present invention;

FIG. 3 is a lateral view of an external box structure with inner and outer tracks of the present invention; and

FIG. 4 is a bottom view of an external box structure with inner and outer tracks of the present invention.

### DETAILED DESCRIPTION OF PREFERRED BEST MOLDS

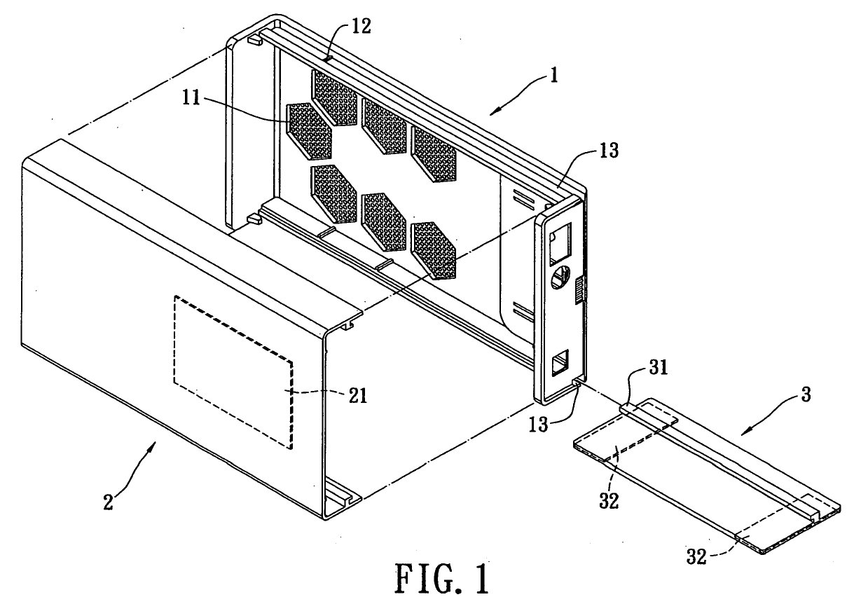

Referring to FIG. 1, the present invention provides an external box structure with inner and outer tracks that includes a casing body 1, a cover body 2, and a fixed board 3. The casing body 1 is a metallic casing body. The casing body 1 has a heat-dissipating net structure 11 disposed on a bottom side thereof for dissipating heat from the hard disk. The casing body 1 has two positioning blocks 12 disposed on two sides thereof for restricting the fixed board 3. The cover body 2 has a heat-dissipating pad 21 disposed on an inner surface thereof for dissipating heat from the hard disk. The cover body 2 is assembled on the casing body 1 and has two first retaining portions 13 (such as two inner tracks) respectively formed on two sides thereof. Hence, each positioning block 12 is disposed on each corresponding first retaining portion 13 for restricting the fixed board 3.

The fixed board 3 has a second retaining portion 31 such as an outer track. Because the second retaining portion 31 slidably mates with any one of the two first retaining portions 13 for fixing the casing body 1 on the fixed board 3 and the position of the fixed board 3 is restricted by the corresponding positioning block 12, the external box structure is positioned on the fixed board 3 in a lateral direction. Hence, the present invention reduces the amount of required space. Moreover, the fixed board 3 has two fixed portions 32 disposed on a bottom side thereof for preventing the fixed board 3 from sliding.

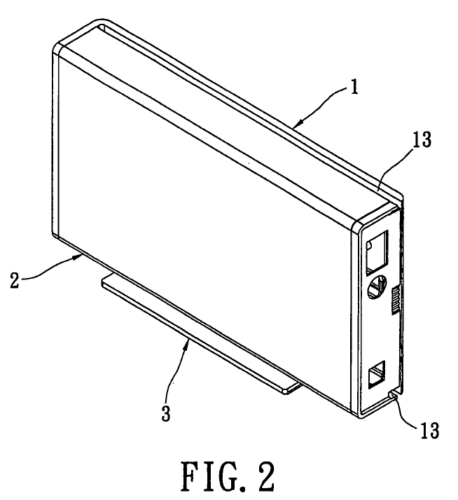

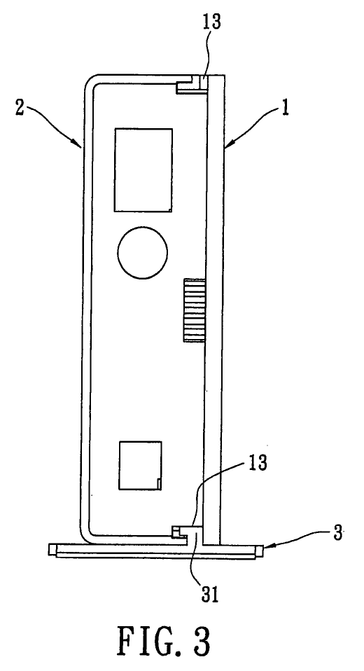

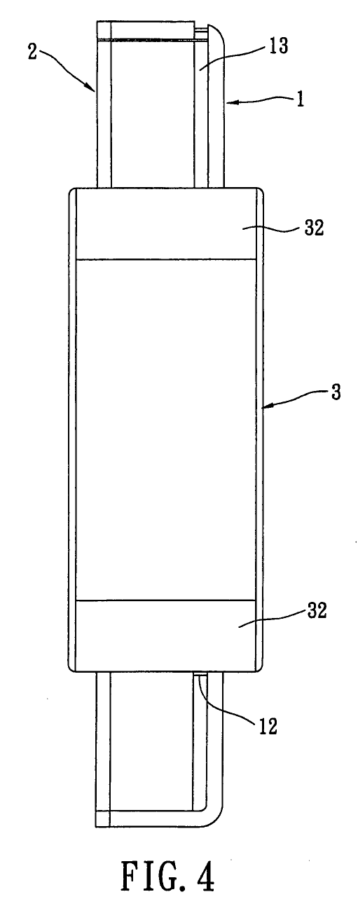

Referring to FIGS. 2 to 4, the external box structure is positioned on the fixed board 3 in a lateral direction, so that the present invention can improve the defect of prior external box positioned in a horizontal direction.

In conclusion, the external box structure of the present invention has the following advantages:

(1) The heat-dissipating net structure 11 and the heat-dissipating pad 21 are used to dissipate heat from the hard disk.

(2) The second retaining portion 31 slidably mates with one of the two first retaining portions 13 for easily fixing the casing body 1 on the fixed board 3.

(3) The position of the fixed board 3 is restricted by the corresponding positioning block 12.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An external box structure with inner and outer tracks, comprising:
a casing body;
a cover body assembled on the casing body and having two first retaining portions respectively formed on two sides thereof; and
a fixed board having a second retaining portion;
wherein the second retaining portion slidably mates with any one of the two first retaining portions for fixing the casing body on the fixed board.

2. The external box structure as claimed in claim 1, wherein the casing body is a metallic casing body.

3. The external box structure as claimed in claim 1, wherein the casing body has a heat-dissipating net structure disposed on a bottom side thereof.

4. The external box structure as claimed in claim 1, wherein each of the first retaining portions has a positioning block for restricting the fixed board.

5. The external box structure as claimed in claim 1, wherein the cover body has a heat-dissipating pad disposed on an inner surface thereof.

6. An external box structure with inner and outer track, comprising:
a casing body; and
a cover body assembled on the casing body and having two first retaining portions respectively formed on two sides thereof.

7. The external box structure as claimed in claim 6, wherein the casing body is a metallic casing body.

8. The external box structure as claimed in claim 6, wherein the casing body has a heat-dissipating net structure disposed on a bottom side thereof.

9. The external box structure as claimed in claim 6, further comprising a fixed board that has a second retaining portion, wherein the second retaining portion slidably mates with any one of the two first retaining portions for fixing the casing body on the fixed board.

10. The external box structure as claimed in claim 6, wherein each first retaining portion has a positioning block for restricting the fixed board.

11. The external box structure as claimed in claim 6, wherein the cover body has a heat-dissipating pad disposed on an inner surface thereof.
